(19) United States
(12) Patent Application Publication
(10) Pub. No.: US 2025/0337374 A1
(43) Pub. Date: Oct. 30, 2025

(54) MODULAR CIRCUITS

(71) Applicant: Cirrus Logic International Semiconductor Ltd., Edinburgh (GB)

(72) Inventors: John P. LESSO, Edinburgh (GB); John L. MELANSON, Austin, TX (US)

(73) Assignee: Cirrus Logic International Semiconductor Ltd., Edinburgh (GB)

(21) Appl. No.: 18/647,380

(22) Filed: Apr. 26, 2024

(51) Int. Cl. H03F 3/217; H04L 25/49

(52) U.S. Cl. CPC H03F 3/217; H04L 25/4902; H03F 2200/171

(57) ABSTRACT

This application relates to methods and apparatus for modulator circuits, for outputting a modulated signal for driving a switching output stage. A first digital modulator generates the modulated signal based on an input signal modified by a correction signal. A second digital modulator generates a feedforward signal from the input signal, which is filtered by a first low-pass filter to provide a filtered feedforward signal. The correction signal is generated by an error path that processes an error signal which is generated as a difference between the filtered feedforward signal and a filtered feedback signal. The filtered feedback signal corresponds to a received feedback signal, indicative of an output from the switching output stage, with low-pass filtering applied. The error path has a loop filter with an analog input stage and the received feedback signal is applied to the error path downstream of the analog input stage for phase lead compensation.

The field of representative embodiments of this disclosure relates to methods, apparatus and/or implementations concerning or relating to modulator circuits for switched mode amplifiers, e.g. class-D amplifiers, in particular to modulator circuits for class-D amplifiers with an error feedback configuration.

Class-D amplifiers, also referred to as switched-mode amplifiers, are used in a variety of applications and can have advantages in terms of power efficiency compared to linear amplifiers. Class-D amplifiers typically comprise a modulator circuit for receiving an input signal and generating a suitably modulated signal, e.g. a PWM (pulse-width-modulation) signal for controlling a switching output stage, which may, or may not, be integrated with the modulator. The modulator circuit may be configured to operate in a closed-loop manner and may thus receive a feedback signal indicative of an output signal from the output stage. The feedback signal may be subtracted from a feedforward signal indicative of the input signal to determine any error between the input signal and the output signal, and the resultant error signal may be filtered by an error loop filter to provide a correction signal which is applied to the input signal. However, the feedback signal will generally have some PWM or other modulation tones, which generally requires at least an input stage of the error loop filter to be a relatively high-performance component able to cope with the presence of high frequency noise and residual modulation tones. This generally requires the use of relatively large components with relatively high-power consumption and in general there is a desire for smaller and/or lower power implementations.

Embodiments of the present disclosure relate to methods and apparatus for modulators for class-D amplifiers and the like that at least mitigate at least some of above-mentioned issues.

According to an aspect of the disclosure there is provided a modulator circuit for outputting a modulated signal for driving a switching output stage based on a digital input signal. The modulator circuit comprises: a forward signal path comprising a first digital modulator configured to generate said modulated signal based on said digital input signal as modified by a digital correction signal and a feedforward path comprising: a second digital modulator configured to generate a feedforward signal based on said digital input signal; and a first low-pass filter configured to apply low pass filtering to said feedforward signal to provide a filtered feedforward signal. A first feedback node is configured to receive a first feedback signal indicative of an output signal output from the switching output stage and an error path is configured to process an error signal to generate the digital correction signal. The error signal is generated as a difference between the filtered feedforward signal and a filtered feedback signal, wherein the filtered feedback signal corresponds to the first feedback signal with low-pass filtering applied. The error path comprises an error loop filter with an analog input filter stage and the modulator circuit is configured to apply the first feedback signal to a first node of the error path downstream of the analog input filter stage as a feedback compensation signal for phase lead compensation.

In some implementations, the modulator circuit may be further configured to apply the feedforward signal, prior to filtering by the first low-pass filter, to the first node of the error path as a feedforward compensation signal for phase lead compensation. The first feedback signal and the feedforward signal may be applied to the first node of the error path via respective gain elements to provide the feedback compensation signal and the feedforward compensation signal respectively. The modulator circuit may, in some cases, be further configured, for at least one additional node of the error path downstream of the analog input filter, to apply the first feedback signal and the feedforward signal to that additional node of the error path, via respective gain elements, so as to provide an additional feedback and feedforward compensation signals for phase lead compensation at that additional node.

The first node of the error path May be at the output of the analog input filter stage. The error loop filter may comprise at least one additional filter stage downstream of the first node of the error path.

The modulator circuit may further comprise a second low-pass filter, and the second low-pass filter may be configured to receive and low-pass filter the first feedback signal to provide the filtered feedback signal.

In some implementations, the modulator circuit may further comprise a second feedback node, for receiving a second feedback signal, wherein the second feedback signal corresponds to the output signal from the output stage as low-pass filtered by an output filter. The modulator circuit may be configured to use the second feedback signal as the filtered feedback signal.

The first low-pass filter may comprise a finite-impulse-response filter. In some implementations, the first low-pass filter may be an adaptive filter and a filter controller may be configured to adapt at least one filter parameter of the adaptive filter to minimise a defined component in the error signal. The defined component in the error signal may comprise a signal component at a modulation tone frequency.

In some implementations, the error loop filter may comprise a hybrid filter comprising one or more analog filter stages, a quantiser and at least one digital filter stage, wherein the analog input filter stage is one of the one or more analog filter stages.

In some implementations, the first and second digital modulators may comprise digital pulse-width-modulation modulators.

The modulator circuit may be implemented as an integrated circuit. The output stage may, in some cases be implemented as part of the same integrated circuit or as a separate integrated circuit. In either case, the modulator circuit may be implemented as part of an amplifier system comprising the modulator circuit and the output stage. The amplifier system may further comprise an output filter in an output path configured to low-pass filter the output signal from the output stage. In which case, the first feedback signal may be tapped from the output of the output stage upstream of the output filter and the filtered feedback signal may be tapped from the output of the output filter. The output filter may be an LC filter.

In another aspect there is provided a modulator circuit for outputting a modulated signal for driving a switching output stage based on a digital input signal, the modulator circuit comprising: a forward signal path comprising a first digital modulator configured to generate the modulated signal based on the digital input signal as modified by a digital correction signal, and an error path configured to generate the digital correction signal based on an error signal, wherein the error signal is generated as a difference between a filtered feedback signal and a filtered feedforward signal. The filtered feedback signal is a feedback signal indicative of an output signal from the output stage which has been low-pass filtered and the filtered feedforward signal is a feedforward signal generated from the digital input signal by a second digital modulator and which has been low-pass filtered. The modulator circuit is configured to apply a first compensation signal for phase lead compensation to a node of the error path which is downstream of a first filter stage of the error path, where the first compensation signal corresponds to the output signal from the output stage without low-pass filtering.

The modulator circuit may be further configured to apply a second compensation signal for phase lead compensation to the node of the error path which is downstream of a first filter stage of the error path, where the first compensation signal corresponds to the feedforward signal from the second digital modulator without low-pass filtering.

In another aspect there is provided a modulator circuit for outputting a modulated signal for driving a switching output stage based on a digital input signal, the modulator circuit being configured to: receive a first feedback signal indicative of an output signal from the output stage; receive or generate a second feedback signal corresponding to the first feedback signal to which low-pass filtering has been applied; generate an error signal as a difference between the second feedback signal and a feedforward signal indicative of the digital input signal; process the error signal in an error path comprising at least a first analogue integrator stage; and apply the first feedback signal to the error path downstream of the first analogue integrator stage.

It should be noted that, unless expressly indicated to the contrary herein or otherwise clearly incompatible, then any feature described herein may be implemented in combination with any one or more other described features.

For a better understanding of examples of the present disclosure, and to show more clearly how the examples may be carried into effect, reference will now be made, by way of example only, to the following drawings in which:

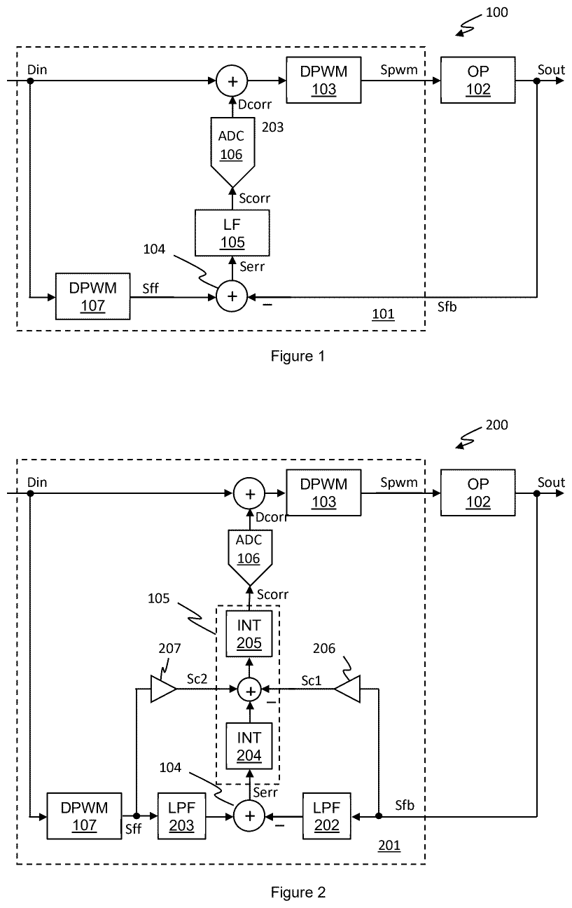

FIG. 1 illustrates one example of a class-D amplifier system;

FIG. 2 illustrates one example of a class-D amplifier system with a modulator circuit with low-pass filtering and phase lead compensation according to an embodiment;

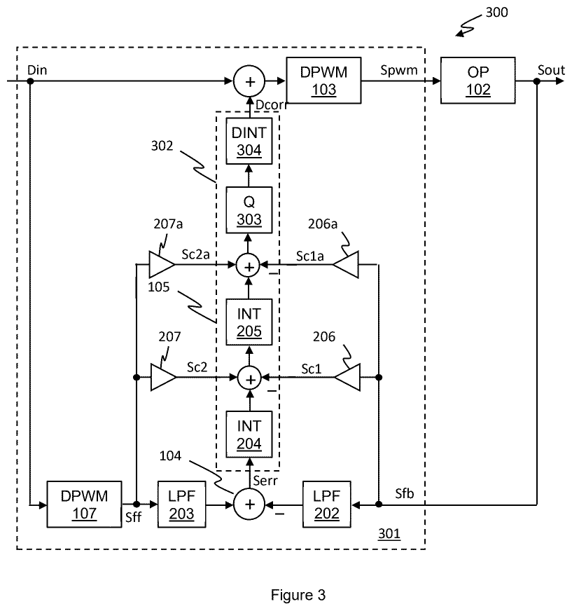

FIG. 3 illustrates an example of a class-D amplifier system with a modulator circuit with a hybrid error filter;

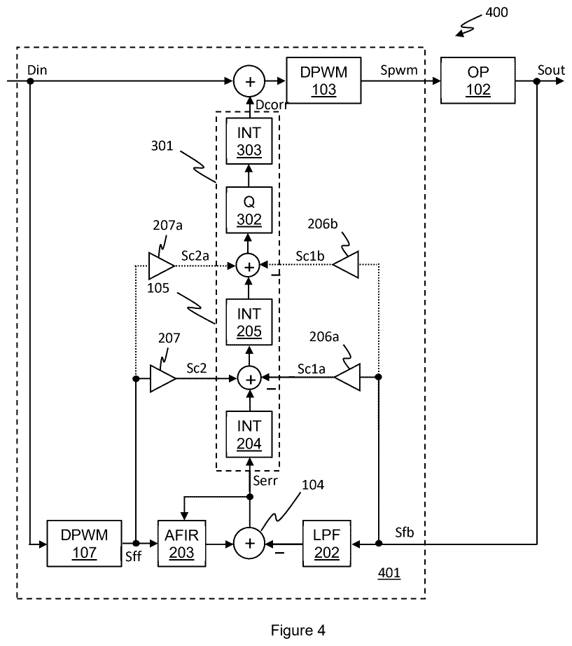

FIG. 4 illustrates an example of a class-D amplifier system with a modulator circuit with adaptive low-pass filtering of the feedforward signal;

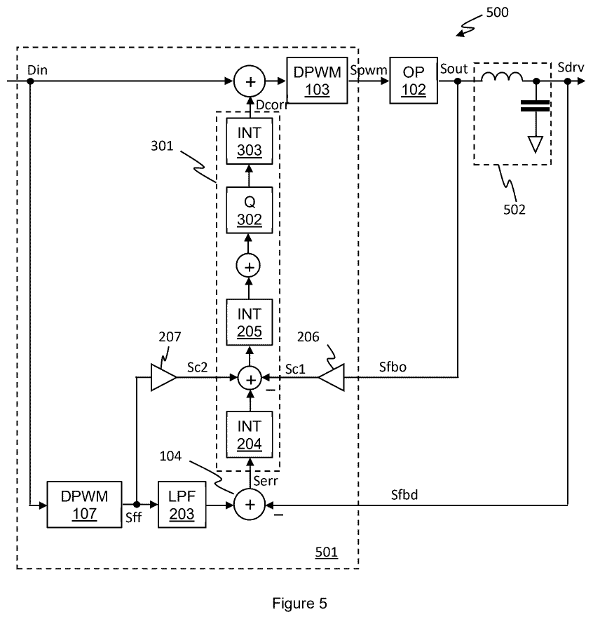

FIG. 5 illustrates an example of a class-D amplifier system with a modulator circuit with an LC output filter; and

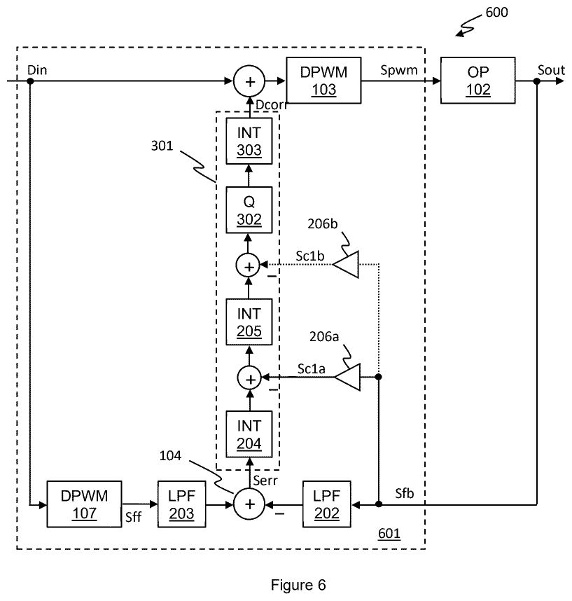

FIG. 6 illustrates an example of a class-D amplifier system with a modulator circuit with asymmetric phase lead compensation.

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

FIG. 1 illustrates one example of a class-D amplifier system 100 that has been previously proposed. The amplifier system 100 comprises a modulator circuit 101 configured to receive a digital input signal Din and to generate a modulated signal, Spwm, for driving switching output stage 102, e.g. a class-D output stage, to generate an output signal Sout for driving a load (not illustrated in FIG. 1).

In the example of FIG. 1, the modulator circuit 101 comprises a first digital modulator 103, which in this example is a digital PWM (pulse-width-modulation) modulator, which is arranged in the modulator forward signal path of the modulator circuit 101 to receive the digital input signal Din, as modified by a digital correction signal Dcorr, and provide a digital PWM signal as the modulated signal Spwm for driving the output stage 102.

To generate the digital correction signal Dcorr, an analog feedback signal Sfb, indicative of the output signal Sout, is fed-back to modulator circuit 101 and supplied, via a modulator feedback path to an error node 104, where it is effectively subtracted from a feedforward signal Sff, indictive of the input signal Din, from a modulator feedforward path to provide an error signal Serr. In other words, the error signal Serr is generated as the difference between the feedback signal Sfb and the feedforward signal Sff This error signal Serr is then processed in an error path to provide the digital correction signal Dcorr, and in the example of FIG. 1, the error path comprises an error loop filter 105 and analog-to-digital converter (ADC) 106. Note it will be understood that in some implementations the error node 104 could be a differential input node for the error loop filter 105, with the signals being applied so that only the difference is processed as the error signal Serr.

In the example of FIG. 1, the modulator feedforward path comprises a second digital modulator 107. This second digital modulator 107 may be matched to first digital modulator 103, e.g. in terms of modulation frequency, so that modulation tones or other modulation components introduced into the modulated signal Spwm by operation of the first digital modulator 103 have substantially matching tones or components in the feedforward signal Sff, which tones should thus be cancelled at the error node 104. It will be understood that the feedforward signal Sff should also be correctly matched in terms of propagation delay and gain to the feedback signal Sfb (including the effect of the output stage 102 and any off-chip forward signal path and feedback path), so that the signal content in both signals due to the input signal Din correctly cancels by subtraction. FIG. 1 only illustrates the second digital modulator 106 in the modulator feedforward path for clarity, which may be configured to provide at least some of the gain and delay matching, but it will be understood that there may be other components in the modulator feedforward path to provide the desired matching.

However, it is practically difficult to ensure that the out-of-band power, e.g. modulation tones and quantization errors, in the feedforward signal Sff exactly match those in the feedback signal Sfb, and thus some mismatch will be expected in practice and this mismatch will result in high frequency noise in the error signal Serr at the error node 104. Thus, in a practical implementation, the error loop filter 105 must be configured to be able to cope with such high frequency noise, which generally requires a high-performance error loop filter 105, or at least a high-performance input stage for the error loop filter 105, which can add to the circuit area, power consumption and/or cost of the error loop filter 105.

Embodiments of the present disclosure provide modulator circuits for a class-D amplifier system which at least mitigate at least some of these issues.

FIG. 2 illustrates an example of a class-D amplifier system 200 that includes a modulator circuit 201 according to an embodiment, in which similar components to those discussed with reference to FIG. 1 are identified by the same references. The modulator circuit 201 of FIG. 2 comprise a first digital modulator 103, e.g. a digital PWM modulator, configured to receive a digital input signal Din as modified by a digital correction signal Dcorr and to generate a modulated signal, Spwm, for driving a class-D output stage 102.

For audio applications, the digital input signal Din may be an audio signal and the output stage 102 may be configured to provide an output signal Sout for driving an audio output transducer (not illustrated in FIG. 2), such as a loudspeaker. The output stage 102 may be any suitable switching output stage for modulating at least one output node between selected switching voltages with a duty cycle defined by the modulated signal Spwm, and could, for example, be a half-bridge output stage for driving the transducer in a single-ended configuration or could be a full-bridge output stage for driving the transducer in a bridge-tied-load configuration, as would be understood by one skilled in the art. Embodiments of the present disclosure are suitably for audio applications, but it will be understood that the disclosure is not limited to audio and a modulator circuit according to an embodiment could be used in other applications as part of a class-D or switched mode driver for driving some other type of load.

The output stage 102 may be integrated with the modulator circuit 201 as part of the same integrated circuit (IC), i.e. the output stage 102 may be on-chip with the modulator circuit 201. In some implementations, however, the output stage 102 may be formed as part of a separate integrated circuit to the modulator circuit 201, with the modulator circuit IC having suitable connections for connecting to the output stage IC, possibly as part of the same IC package or as separate IC packages in a host device. For instance, for some applications there may be advantages in implementing the modulator circuit 201 as part of an IC formed using conventional silicon processing technologies, whilst using compound semiconductor processing, e.g. GaN processing, for the IC for the output stage 102.

In the modulator circuit 201 of FIG. 2, the modulator circuit 201 receives a feedback signal Sfb indicative of the output signal Sout which is output from the output stage 102, which may be tapped from the output of the output stage 102 or from some downstream node.

In a similar manner as discussed with respect to FIG. 1, the feedback signal Sfb may be supplied to an error node 104 via a modulator feedback path to be subtracted from a feedforward signal Sff, with the feedforward signal Sff being generated from the digital input signal by a modulator feedforward path that that comprises a second digital modulator 107. Again it will be noted that the error node 104 could, in some embodiments, be a differential input node for the error loop filter 105. However, in the embodiment of FIG. 2, the feedback signal Sfb and feedforward signal are subjected to low-pass filtering before subtraction. In the example of FIG. 2, the modulator circuit 201 comprises a first low-pass filter 202 in the modulator feedback path for applying low-pass filtering to the received feedback signal Sfb and a second low-pass filter 203 in the modulator feedforward path for applying low-pass filtering to the feedforward signal Sff output from the second digital modulator 107, although other filter arrangements may be implemented as will be discussed in more detail below. It is thus the filtered versions of the feedback signal Sfb and the feedforward signal Sff that are subtracted from one another to provide the error signal Serr.

This low-pass filtering of the feedback signal Sfb and feedforward Sff reduces the amount of high-frequency noise in the resultant error signal Serr and the requirement for exact matching of the modulation tones, and hence eases the performance requirements for the input of error loop filter 105, compared to the example of FIG. 1. The low-pass filters 202 and 203 may be implemented as unpowered, passive filters and thus can be relatively straightforward to implement. However, the low pass filtering results in a propagation delay, which limits the error loop gain e.g. the gain of the error path, that can be applied without instability. A limited error loop gain limits the ability of the error loop to correctly adjust for any error in the output signal, which can limit the performance of the amplifier system, e.g. in terms of THD (total harmonic distortion) and/or PSSR (power-supply-rejection-ratio). The presence of the low-pass filters 202 and 203 to apply filtering to the feedback and feedforward signals Sfb and Sff respectively can thus advantageously ease the requirements for the error loop filter 105 but, on their own, this would be at the expense of a generally worse performance and thus such low-pass filtering is typically avoided.

In embodiments of the present disclosure, to mitigate the issue of reduced loop gain due to the delay introduced by the low-pass filtering, the feedback signal Sfb, prior to low-pass filtering being applied, may be used to provide a first compensation signal Sc1 to a node of the error path downstream of a first filter stage of the error loop filter 105. Likewise, the feedforward signal Sff, prior to the low-pass filtering being applied, may be used to provide a second compensation signal Sc2 to that node of the error path. These first and second compensation signals Sc1 and Sc2, provided respectively by the feedback signal Sfb and feedforward signal Sff prior to the low-pass filtering, effectively act as phase lead compensation signals that at least partly compensate for the delay introduced by the low-pass filters 202 and 203. The application of these compensation signals to the error path means that the correction signal Scorr will effectively respond more quickly to changes in the feedback signal Sfb and feedforward signal Sff. This allows a greater loop gain to be implemented than otherwise would be the case, which can provide better performance. The (unfiltered) feedback signal Sfb may be applied to the error path via a first gain element 206, which applies a defined gain, so as to provide the first compensation signal Sc1 and the (unfiltered) feedforward signal Sff may be applied to the error path via a second gain element 207, which likewise applies a defined gain, so as to provide the second compensation signal Sc2. In some applications the gain elements 206 and 207 may be implemented as suitable resistors. As the first compensation signal Sc1 is applied to provide a phase lead compensation for the filtered feedback signal, which, in this example, is subtracted from the filtered feedforward signal, the first compensation may be applied to the error path by subtraction. As second compensation signal Sc2 is applied to provide a phase lead compensation for the filtered feedforward signal, which, in this example, is effectively additively applied to the error node, the second compensation signal Sc2 may be applied to the error path by addition. In general, the phase lead compensation signals Sc1 and Sc2 should be consistent with the filtered feedback and filtered feedforward signals in terms of how they are applied to the error path.

By applying low-pass filtering to the feedback signal Sfb and feedforward signal Sff prior to subtraction at the error node 104, the benefits of reduced performance requirements for the input stage of the error loop filter 105 can be realised, whilst using the unfiltered signals to provide compensation signals Sc1 and Sc2, for phase lead compensation in the error path, can mitigate against the effects of the filtering delay, thus preserving performance. The low-pass filtering of the feedback signal Sfb and feedforward signal Sff can also advantageously also reduce the jitter sensitivity of the amplifier system 200.

FIG. 2 illustrates that the first and second compensation signals Sc1 and Sc2 may be applied to a node of the error path which is at the output of a first filter stage 204 of the error loop filter 105, which may be first integrator stage. Typically the error loop filter 204 may comprise multiple integrator stages and FIG. 2 illustrates an example in which the error loop filter also has a second filter stage 205, which may be a second integrator stage 205 and the first and second compensation signals Sc1 and Sc2 may be applied to a node which is between the first and second integrator stages 204 and 205.

This arrangement is advantageous in that the first integrator stage 204 receives only the error signal Serr generated as the difference between the filtered feedback and feedforward signals Sfb and Sff, which eases the design considerations and performance requirements for this first integrator stage 204. The compensation signals Sc1 and Sc2 bypass the low-pass filters 202 and 203 respectively, and also bypass the first integrator stage 204 to provide phase lead compensation at the output of this first integrator stage 204. Whilst a signal component introduced by the compensation signals Sc1 and Sc2 thus does not benefit from any noise suppression from the first integrator stage 204, there is filtering of this signal component by the second integrator stage 205. It will be understood that the compensation signals Sc1 and Sc2, corresponding to the feedback and feedforward signals Sfb and Sff may introduce some noise component, but as these signals are applied to the error path downstream of the first integrator stage 204, the noise is effectively input referred through an integrator, which provides a relatively large gain. Any distortion due to these signal components is effectively attenuated at the frequency of interest by the gain of the integrator stage 204. It will also be understood other implementations could have different number of filter stages for the error loop filter 105 and the compensation signals Sc1 and Sc2 could be applied to the input or output of any of the filter stages depending on the amount of phase lead compensation desired and also the amount of filtering desired for the compensation signal components in the error path. In some implementations, compensation signals may be applied at more than one point in the error path as will be described in more detail below.

In the example of FIG. 2, the error loop filter 105 is implemented as an analogue filter which generates a correction signal Scorr, which is digitized by ADC 106 to provide the digital correction signal Dcorr which is applied to the input signal in the main forward signal path of the modulator circuit 101. However, in some embodiments the error loop filter may be implemented as a hybrid filter that receives an analog input and produces a digital output.

FIG. 3 illustrates an example of a class-D amplifier system 300 that includes a modulator circuit 301 according to an embodiment, in which similar components to those discussed with reference to FIG. 2 are identified by the same references.

In the example of FIG. 3, the error loop filter is implemented as a hybrid filter 302. The hybrid filter 302 comprises one or more analog filter stages, in this example first and second integrator stages 204 and 205 such as discussed with reference to FIG. 2. The output from the analog stages is quantised by a quantiser 303 and filtered by at least one digital filter stage, in this example a digital integrator stage 304, to provide the digital correction signal. It will be understood be one skilled in the art that the hybrid filter 302 may comprise some filter feedforward and/or feedback paths (not illustrated in FIG. 3) around some of the filter stages to provide a desired filter transfer function.

In a similar manner as discussed with reference to FIG. 2, compensation signals may be applied to a node in the analogue part of the error path. The example of FIG. 2 illustrates that compensation signals Sc1 and Sc2 may be applied to the error path at the output of the first integrator stage/input to the second integrator stage as discussed above but, in this example, the feedback signal Sfb and feedback signal Sff are also used to provide additional compensations signals Sc1a and Sc2a respectively, via respective gain elements 206a and 206b, that are applied to the output of the second integrator stage 205. These addition compensation signals can provide additional phase lead compensation and help stabilise the error loop for a desired error loop gain with the relatively gains provided by gain elements 206 and 206a, and likewise 207 and 207a, being set so as to provide the desired amount of compensation at each stage of the error path. In this case the compensation signals Sc1a and Sc2a are applied to a node of the error path upstream of the quantizer and these added signal components will be filtered by the digital integrator stage 304. It will, of course, be understood that just one set of compensation signals, i.e. Sc1 and Sc2 or Sc1a and Sc2a could be used in an alternative implementation.

In the examples of FIGS. 2 and 3, low-pass filters 202 and 203 provide low-pass filtering of the respective feedback and feedforward signals Sfb and Sff. The low-pass filters 202 and 203 may be implemented by any suitable low-pass filter, and as noted, may be implemented as passive filters. In some applications, the low-pass filter 203 in the feedforward path may be implemented as an analog finite impulse response (FIR) filter, which may ease design. The low-pass filters 202 and/or 203 may be configured as boxcars filters to minimize jitter and reference noise sensitivity.

In some implementations, the low-pass filter 203 in the feedforward path may be an adaptive filter, as illustrated in FIG. 4. FIG. 4 illustrates a class-D amplifier system 400 that includes a modulator circuit 401 according to an embodiment, in which similar components to those discussed with reference to FIGS. 2 and 3 are identified by the same references, and where the filter 203 in the feedforward path is an adaptive filter, for example an adaptive finite impulse response (AFIR) filter, which is adapted in the response to an indication of the error signal Serr. The adaptive low-pass filter 203 may be adapted so that the transfer function of the feedforward path matches the transfer function that applies for the feedback signal Sfb, which can improve the cancellation of common signal content in the two signals to leave the correct error.

A filter controller (not separately illustrated) of the adaptive filter 203 may be configured to adapt one or more filter parameters, e.g. the coefficients or weightings of the filter 203, to minimize some defined signal component in the error signal Serr, which may for instance be any signal component at the modulation tone frequency of the first and second digital modulators 103 and 107. FIG. 4 illustrates that the error signal Serr from the error node 104 may be used for adapting the adaptive filter 203, but in some implementation the output from the first integrator stage 204 could be used for adapting the adaptive filter 203.

In some implementations, the filter controller of the adaptive filter 203 may be configured to monitor the relevant signal content in the error signal Serr on a relatively continuous basis, and the filter 203 may be adapted as required on such a relatively continuous basis. However, in some implementations, whilst the monitoring may be relatively continuous, the filter controller may be configured to, after an initial adaptation on start-up, only apply adaption periodically and/or if the relevant monitored signal content crosses some threshold, i.e. the filter 203 may not be adapted in a continuous manner by the filter controller, but only on a periodic basis or when it is determined that some adaptation is required to maintain the filter performance within a defined tolerance. In some implementations it may be sufficient to adapt the filter 203 in a start-up calibration process only, and further monitoring and adaptation in subsequent use may not be required.

The examples of FIGS. 2 to 4 illustrate the feedback signal Sfb being tapped from the output of the output stage and being filtered by a low-pass filter 202 in the modulator feedback path. In some implementations, there may be some filtering applied to the output signal Sout generated by the output stage 102 in the downstream path to the load. For instance, in some applications, it may be beneficial to have an output filter for applying low-pass filtering of the output signal Sout, to provide a drive signal Sdrv for the load. When such as output filter is present, the feedback signal Sfb may be tapped from the output path of the output stage 102 upstream of the output filter and processed as discussed with respect to any of FIGS. 2 to 4.

However, in some implementations, it may be advantageous to include the output filter within the error loop.

FIG. 5 illustrates an example of a class-D amplifier system 500 that includes a modulator circuit 501 according to an embodiment, in which similar components to those discussed previously are identified by the same references, and which includes an output filter within the error loop. FIG. 5 illustrates that the output signal Sout which is output from the output stage 102 is filtered by a downstream output filter 502, to provide a drive signal Sdrv for driving the load (not illustrated). In this example, the output filter 502 is illustrated as an LC (inductor-capacitor) filter with a series inductor in the output path and a capacitor connected between the output path and a defined voltage. Such an LC filter may typically be implemented by components which are external, i.e. off-chip, to the output stage circuit, but it will be understood that other types of output filter, such as RC filters, may be used in some embodiments which could be integrated with the output stage 102.

In the example of FIG. 5 the modulator circuit 501 is configured to receive two feedback signals, a first feedback signal Sfbo indicative of the output signal Sout which is tapped from upstream of the output filter 502 and a second feedback signal Sfbd tapped from downstream of the output filter 502 and thus indicative of the drive signal Sdrv.

To include the output filter 501 within the error loop, the second feedback signal Sfbd of the drive signal Sdrv is used to determine the error signal Serr. The second feedback signal Sdrv is thus supplied to the error node 104. In this case, the second feedback signal Sfbd has already been subjected to low-pass filtering by the operation of the output filter 501. There may thus be no need to apply any additional low-pass filtering in the modulator feedback path and the second feedback signal Sfbd may be supplied to the error node without any additional filtering, although in some implementations some further filtering could be applied in the modulator feedback path if desired. The feedforward signal Sff is thus low-pass filtered by low-pass filter 203 in a similar manner as discussed above and the filtered feedforward signal supplied to the error node 104. As some output filters, in particular LC output filters, may exhibit some variability in use, the low-pass filter 203 in the feedforward path may be advantageously implemented as an adaptive filter as discussed with reference to FIG. 4.

As the second feedback signal Sfbd has been subjected to the filtering delay of the output filter 501, there would be limited benefit in using the second feedback signal Sfbd as a phase lead compensation signal, and were only the second feedback signal Sfbd available, the loop gain would need to be limited as discussed above to maintain stability, with a consequent impact on performance. In this case the benefits of including any error due to the output filter 501 within the error loop may be offset by the limitation on loop gain.

In the embodiment of FIG. 5, therefore, the first feedback signal Sfbo is also provided, which is indicative of the output signal Sout prior to filtering by the output filter 502. The first feedback signal Sfbo is used to provide at least one compensation signal, and in the example of FIG. 5 is applied via gain element 206 to provide a compensation signal Sc1 at the output of the first integrator stage 204 in a similar manner as discussed above with reference to FIGS. 2 to 4. The use of the first feedback signal Sfbo to provide one or more compensation signals for phase lead compensation thus provides the benefits of allowing a higher loop gain and hence better performance, whilst using the second feedback signal Sfbd, indicative of the drive signal Sdrv, to generate the error signal means that the effects of the output filter 502 is included within the error loop and the operation of the error loop suppresses the non-linearity due to the output filter 502, i.e. the error loop operates to correct the error in the drive signal Sdrive which actually drives the load, which can thus improve performance.

The examples of FIGS. 2 to 5 illustrate that the compensations signals may be applied in a generally symmetric manner, that is, a feedback compensation signal which is derived from the unfiltered feedback signal Sfb (or Sfbo) is applied to a node of the error path along with a corresponding feedforward compensation signal derived from the unfiltered feedback signal Sff, e.g. Sc1 and Sc2. In some implementations, as illustrated in FIG. 6, the feedforward compensation signal(s) derived from the feedforward signal Sff may be omitted. FIG. 6 illustrates a class-D amplifier system 600 that includes a modulator circuit 601 according to an embodiment, in which similar components to those discussed previously are identified by the same references.

FIG. 6 illustrates that a feedback compensation signal Sc1 (and possibly at least one additional compensation signal Sca1) may be generated from the feedback signal Sfb prior to filtering and applied to the error, but in this case without a matching feedforward compensation signal from the feedforward signal. As a feedforward compensation signal derived from the feedforward signal Sff is outside the main feedback loop, the relevant compensation terms provided are less critical. In some cases this could simplify the modulator circuit, but the omission of the matching compensation signal(s) from the feedforward signal Sff may have an impact on the signal transfer function (STF) of the amplifier system.

Embodiments of the present disclose thus provide modulator circuits for driving a switched-mode output stage. Modulator circuits according to the embodiments described herein can be seen as hybrid digital-analog modulator, as the forward signal path can be digital, but the feedback signal is analog and analog combination of the filtered feedback signal with a filtered analog feedforward signal are used to provide an analog error signal, with analog compensation signals being applied in an analog part of an error path for processing the error signal.

Embodiments may be implemented as an integrated circuit. Embodiments may be implemented in a host device, which may be a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. It will be understood that embodiments may be implemented as part of a system provided in a home appliance or in a vehicle. There is further provided a host device incorporating the above-described embodiments.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For some applications, embodiments may be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A modulator circuit for outputting a modulated signal for driving a switching output stage based on a digital input signal, the modulator circuit comprising:
a forward signal path comprising a first digital modulator configured to generate said modulated signal based on said digital input signal as modified by a digital correction signal;
a feedforward path comprising: a second digital modulator configured to generate a feedforward signal based on said digital input signal; and a first low-pass filter configured to apply low pass filtering to said feedforward signal to provide a filtered feedforward signal;
a first feedback node configured to receive a first feedback signal indicative of an output signal output from the switching output stage;
an error path configured to process an error signal to generate said digital correction signal, wherein said error signal is generated as a difference between said filtered feedforward signal and a filtered feedback signal, wherein the filtered feedback signal corresponds to said first feedback signal with low-pass filtering applied and wherein the error path comprises an error loop filter with an analog input filter stage;
wherein the modulator circuit is configured to apply said first feedback signal to a first node of the error path downstream of the analog input filter stage as a feedback compensation signal for phase lead compensation.

2. The modulator circuit of claim 1 wherein the modulator circuit is further configured to apply said feedforward signal, prior to filtering by the first low-pass filter, to the first node of the error path as a feedforward compensation signal for phase lead compensation.

3. The modulator circuit of claim 2 wherein the first feedback signal and the feedforward signal are applied to the first node of the error path via respective gain elements to provide the feedback compensation signal and the feedforward compensation signal respectively.

4. The modulator circuit of claim 3 wherein the modulator circuit is further configured for at least one additional node of the error path downstream of the analog input filter, to apply said first feedback signal and said feedforward signal to that additional node of the error path via respective gain elements so as to provide an additional feedback compensation signal and an additional feedforward compensation signal for phase lead compensation at that additional node.

5. The modulator circuit of claim 1 wherein said first node of the error path is at the output of the analog input filter stage.

6. The modulator circuit of claim 5 wherein the error loop filter comprises at least one additional filter stage downstream of the first node of the error path.

7. The modulator circuit of claim 1 further comprising a second low-pass filter, wherein the second low-pass filter is configured to receive and low-pass filter the first feedback signal to provide said filtered feedback signal.

8. The modulator circuit of claim 1 further comprising a second feedback node for receiving a second feedback signal, wherein the second feedback signal corresponds to the output signal from the output stage as low-pass filtered by an output filter, and the modulator circuit is configured to use the second feedback signal as said filtered feedback signal.

9. The modulator circuit of claim 1 wherein the first low-pass filter is a finite-impulse-response filter.

10. The modulator circuit of claim 1 wherein the first low-pass filter is an adaptive filter and a filter controller is configured to adapt at least one filter parameter of the adaptive filter to minimise a defined component in the error signal.

11. The modulator circuit of claim 10 wherein said defined component in the error signal comprises a signal component at a modulation tone frequency.

12. The modulator circuit of claim 1 wherein the error loop filter comprises a hybrid filter comprising one or more analog filter stages, a quantiser and at least one digital filter stage, wherein said analog input filter stage is one of the one or more analog filter stages.

13. The modulator circuit of claim 1 wherein the first and second digital modulators comprise digital pulse-width-modulation modulators.

14. An amplifier system comprising the modulator circuit of claim 1 and said output stage.

15. The amplifier system of claim 14 further comprising an output filter in an output path configured to low-pass filter the output signal from the output stage.

16. The amplifier system of claim 15 wherein said first feedback signal is tapped from the output of the output stage upstream of the output filter and the filtered feedback signal is tapped from the output of the output filter.

17. The amplifier system of claim 16 wherein the output filter is an LC filter.

18. A modulator circuit for outputting a modulated signal for driving a switching output stage based on a digital input signal, the modulator circuit comprising:
a forward signal path comprising a first digital modulator configured to generate said modulated signal based on said digital input signal as modified by a digital correction signal,
an error path configured to generate said digital correction signal based on an error signal, wherein said error signal is generated as a difference between a filtered feedback signal and a filtered feedforward signal;
wherein the filtered feedback signal is a feedback signal indicative of an output signal from the output stage which has been low-pass filtered and the filtered feedforward signal is a feedforward signal generated from the digital input signal by a second digital modulator and which has been low-pass filtered; and
wherein the modulator circuit is configured to apply a first compensation signal for phase lead compensation to a node of the error path which is downstream of a first filter stage of the error path, where the first compensation signal corresponds to the output signal from the output stage without low-pass filtering.

19. The modulator circuit of claim 18 wherein the modulator circuit is further configured to apply a second compensation signal for phase lead compensation to said node of the error path which is downstream of a first filter stage of the error path, where the first compensation signal corresponds to the feedforward signal from the second digital modulator without low-pass filtering.

20. A modulator circuit for outputting a modulated signal for driving a switching output stage based on a digital input signal, the modulator circuit being configured to:
receive a first feedback signal indicative of an output signal from the output stage;
receive or generate a second feedback signal corresponding to the first feedback signal to which low-pass filtering has been applied;
generate an error signal as a difference between the second feedback signal and a feedforward signal indicative of the digital input signal;
process the error signal in an error path comprising at least a first analogue integrator stage; and
apply the first feedback signal to the error path downstream of the first analogue integrator stage.
